(19) United States
(12) Patent Application Publication
(10) Pub. No.: US 2026/0177581 A1
(43) Pub. Date: Jun. 25, 2026

(54) ADAPTER FOR A DEVICE FOR NON-DESTRUCTIVE TESTING BY MEANS OF ELECTROMAGNETIC RADIATION

(71) Applicant: OFFICE NATIONAL D'ETUDES ET DE RECHERCHES AEROSPATIALES, Palaiseau (FR)

(72) Inventors: Bruno PASSILLY, Palaiseau (FR); Ludovic GAVERINA, Palaiseau (FR)

(21) Appl. No.: 19/125,568

(22) PCT Filed: Oct. 27, 2023
(86) PCT No.: PCT/FR2023/051694

§ 371 Date: Apr. 29, 2025

(30) Foreign Application Priority Data
Oct. 31, 2022 (FR) 2211359

(51) Int. Cl. G01R 1/04; G01R 1/067; G01R 1/073; H01R 12/70

(52) U.S. Cl. CPC G01R 1/0408; G01R 1/0675; G01R 1/07357; H01R 12/7076

(57) ABSTRACT

An adapter for a device for non-destructive testing by use of electromagnetic radiation. The adapter includes a proximal portion configured to be attached to a testing device, and a distal portion including a contact element forming a free end and mounted so as to be movable relative to the proximal portion such that the distal portion deforms when a force is applied to the contact element, the contact element being connected to the deformable member by a ball-and-socket joint or a pivot link, the contact element being parallelepiped in shape.

### TECHNICAL FIELD

The present application relates in general terms to the field of devices and methods for non-destructive testing by electromagnetic radiation, and in particular non-destructive testing by active thermography.

### PRIOR ART

Inspection by active thermography is a conventional non-destructive testing technique. According to this technique, the part to be inspected is illuminated by a heat-provision means, such as a flash lamp, and then the thermal flow radiated by the part is acquired by means of a detector, such as an infrared camera. The diffusion of the heat in the part after illumination thereof can thus be displayed. If the part has defects, the display of the heat diffusion reveals local thermal contrasts and makes it possible to discern the presence of such defects. The means for providing heat by radiation can use various spectral domains, such as the infrared domain or the visible domain.

Active-thermography inspection devices have numerous drawbacks. Whereas the portion of these devices intended to be placed in contact with the part is flat, the parts to be inspected in general have a curvature or a bulge, as is the case with an aircraft fuselage, which has a convex profile, or a tank for petrochemical use, which has a dished profile. This situation poses a difficulty since it is difficult to move the device automatically towards the part to be inspected, since the latter may be damaged.

### DESCRIPTION OF THE INVENTION

One aim of the present application is to remedy the aforementioned drawbacks, by proposing an adapter for a device for non-destructive testing by electromagnetic radiation, the adapter comprising:
a proximal part configured to be attached to a testing device, and
a distal part comprising a contact element forming a free end and mounted so as to be movable with respect to the proximal part so that the distal part deforms when a force is applied to the contact element.

Such an adapter is advantageously and optionally supplemented by the following various features taken alone or in combination:
the contact element has rounded or bevelled edges;
a deformable member connected to the contact element so as to mount the contact element so as to be able to move with respect to the proximal part, the deformable member preferentially being a compression spring, a single-acting cylinder or a double-acting cylinder;
the contact element is rigidly connected to the deformable member, the contact element having a spherical shape;
the contact element is connected to the deformable member via a ball-and-socket or pivot connection, the contact element having a parallelepipedal shape;
the contact element and the deformable member form a first assembly, the adapter comprising a plurality of assemblies;
the contact elements are arranged contiguous in pairs, two contiguous contact elements being directly connected by an elastic element;
the elastic element is a first elastic element, the two contiguous contact elements furthermore being directly connected by a second elastic element, the first and second elastic elements being connected to the contact elements by mounting in parallel;
the adapter extends from the proximal portion to the distal portion along an axial direction, the adapter being hollow so as to have a recess in the axial direction, the recess emerging outside the adapter through the proximal portion and through the distal portion, the adapter comprising an optical-isolation wall surrounding the recess, the wall comprising an external portion opaque to electromagnetic radiation, and an internal portion reflective for electromagnetic radiation, the electromagnetic radiation being intended to be used for the non-destructive testing; and
the optical-isolation wall is deformable, the wall preferentially comprising a fabric, plastics material, portions pleated in an accordion or sections configured to nest together in the axial direction.

The invention also relates to a system for non-destructive testing by electromagnetic radiation comprising:
a device for non-destructive testing by electromagnetic radiation, the device comprising a radiation source and a radiation detector,
an adapter as has been able to be presented above, the proximal portion being rigidly secured to the non-destructive testing device.

Finally, the invention relates to a method for non-destructive testing of a part by radiation, comprising the following steps:
putting a contact element of a testing system in contact with the part,
applying a force to the contact element, and
moving the contact element with respect to the rest of the system under the action of the force and deforming the system according to the shape of the part.

Such a method is advantageously and optionally supplemented by the following steps of emitting, through the inspection system, radiation towards the part, and acquiring, through the inspection system, a temporal response of heat diffusion in the part.

### DESCRIPTION OF THE FIGURES

Other features and advantages of the invention will also emerge from the following description, which is purely illustrative and non-limitative, and must be read with regard to the accompanying drawings, on which:

FIG. 1 is a schematic representation of an adapter according to an embodiment of the invention;

FIG. 2 is a schematic representation of a portion of the adapter shown in FIG. 1; and

FIGS. 3 and 4 are schematic representations of a non-destructive testing system according to an embodiment of the invention.

### DETAILED DESCRIPTION OF THE INVENTION

### Device for Non-Destructive Testing by Electromagnetic Radiation

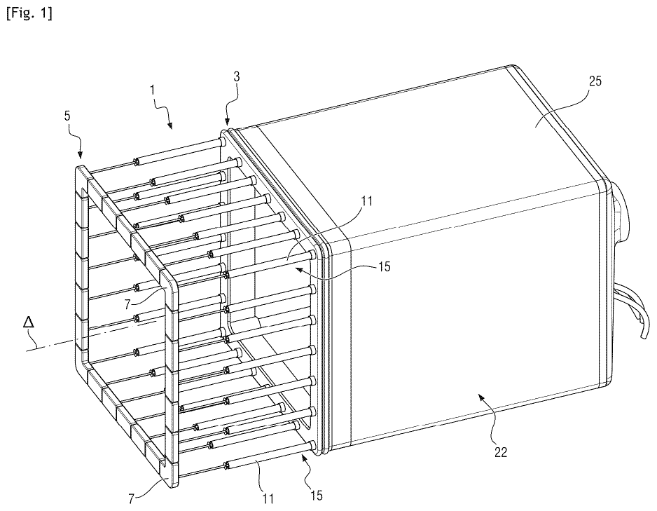

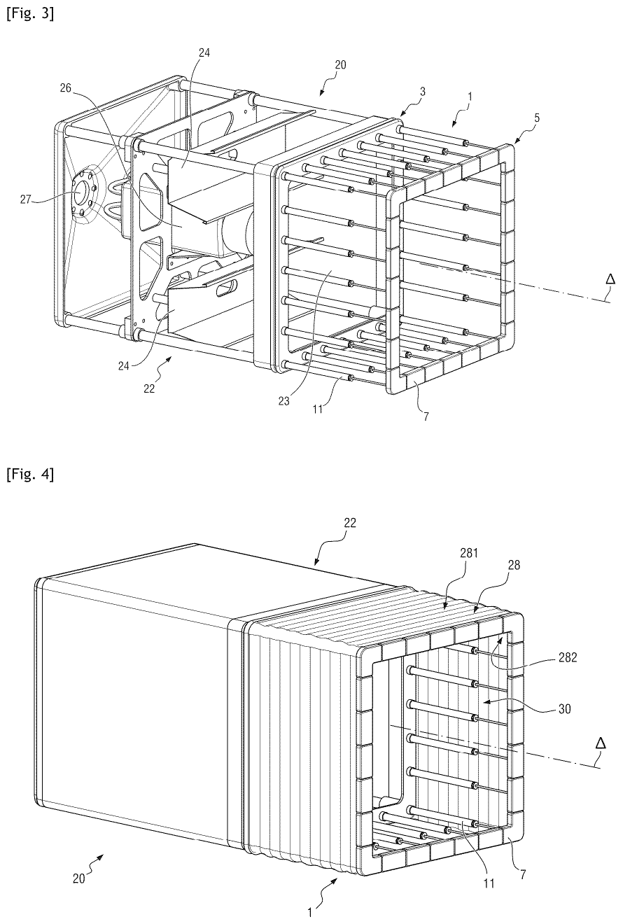

With reference to FIGS. 1, 3 and 4, a device 22 for non-destructive testing by electromagnetic radiation comprises a radiation source 24 and a radiation detector 26.

The radiation source and the radiation detector are located in a housing of the device open towards the outside. The housing has an opening 23 of the device. The radiation source and the radiation detector are oriented facing the opening 23 of the device. This orientation thus defines a front face of the device 22. The opening 23 is for example a planar surface perpendicular to a first direction, a direction which on FIGS. 1, 3 and 4 corresponds to an axial direction Δ.

The source 24 and the detector 26 are oriented towards the outside of the device 22.

A flash lamp, an incandescent lamp, a halogen lamp, a laser diode or an electrical element can be used as a radiation source 24.

The radiation source 24 is configured to emit radiation propagating in the first direction going away from the device 22. The radiation emitted then passes through the opening 23.

An infrared camera, a visible camera or a detector of another spectral domain can be used as a radiation detector 26.

The radiation detector 26 is configured to detect radiation propagating in the first direction approaching the device 22. The radiation received then passes through the opening 23. In particular, the detector 26 can be centred on the first direction.

The control device 22 can be of the active or multispectral thermography type.

The non-destructive testing device 22 also comprises a cowl 25 that covers the device with the exception of the opening 23. The cowl 25, which may be made from plastics material or metal, makes it possible to block electromagnetic radiation arriving on the device outside the opening 23.

The testing device can comprise a cable passage 27 for supplying the source 24 and the detector 26 and for transmitting the information measured by the detector 26.

The cable passage 27 can be provided in the cowl 25, for example at the rear of the device 22, i.e. opposite to the front face of the device 22, the front face defined by the opening 23.

Preferably, the device takes a parallelepipedal shape, the opening taking a rectangular shape.

### Adapter for Device for Non-Destructive Testing by Electromagnetic Radiation

With reference to FIG. 1, an adapter 1 for a device for non-destructive testing by electromagnetic radiation comprises a proximal portion 3 configured to be attached to a device 22 for non-destructive testing by electromagnetic radiation and a distal portion 5 configured to be put in contact with a part to be tested. The part to be tested is not shown on the figures.

The adapter 1 extends in an axial direction Δ from the proximal portion 3 as far as the distal portion 5. In this way, when the proximal portion 3 is attached to a testing device 22 and the distal part 5 is put in contact with a part to be tested, the adapter is located between the testing device 22 and the part to be tested.

Preferably, the adapter takes a parallelepipedal shape, the proximal portion 3 having a rectangular shape in cross section orthogonal to the axial direction Δ. The proximal portion 3 forms a rectangular frame that can be pressed on the non-destructive testing device.

The adapter 1 can be hollow so as to have a recess 30 in the axial direction Δ. The recess 30 emerges outside the adapter 1 through on the one hand the proximal portion 3 and through the distal portion 5. In other words, the adapter 1 has the recess 30 passing right through it in the axial direction Δ.

By attaching the proximal portion 3 to the non-destructive testing device 22, the recess 30 can be put in line with the opening 23, the first direction and the axial direction Δ then coinciding. Radiation emitted by the source 24 in the first direction or respectively radiation propagating in the first direction in the direction of the detector 26 can thus pass through the adapter 1 after having left the source 24 or respectively before reaching the detector 26.

The adapter 1 can also comprise an optical-isolation wall 28 surrounding the recess 30. In this way, radiation arriving on the wall 28 would be stopped.

The wall 28 extends around the axial direction Δ from the proximal portion 3 as far as the distal portion 5. In this way, when the adapter 1 is hollow so as to have the recess 30, only radiation passing through the recess 30 without touching the wall 28 can be transmitted through the adapter.

The adapter can comprise for example a plurality of rods, each rod being attached to the proximal portion 3 and extending in the axial direction Δ around the recess 30. The wall 28 or protection surrounds the plurality of rods and makes it possible for example to form an axial tunnel with a rectangular cross-section emerging outside the adapter. The axial tunnel corresponds to the recess 30. The plurality of rods can comprise four rods, each attached to a corner of the rectangular shape of the proximal portion 3. The plurality of rods can comprise for other rods parallel to the previous ones and distributed on the four sides of the frame.

It can be sought to isolate the radiative exchanges between the device and the part with respect to the exterior environment, i.e. to ensure that the energy emitted by the device towards the part is the only energy received by the part and conversely that the energy emitted by the part towards the device is the only energy received by the device. It can be sought to isolate the radiative exchanges in particular to avoid disturbing the excitation of the part by the device, the diffusion phenomenon and the signal acquired from the diffusion in the part by the detector. It can also be sought to isolate the radiative exchanges to avoid flashes of light dazzling the operators. For this purpose, the wall 28 can comprise an external portion 281 opaque to radiation, such as for example the radiation emitted by the source 24. The external portion 281 of the wall 28 can be made from opaque fabric produced from nylon and cotton, or from polyamide and elastane or from synthetic rubber.

In addition, the wall 28 can comprise for example an internal portion 282 reflective for radiation, such as for example the radiation emitted by the source 24. The internal portion 282 of the wall 28 can comprise a gold-plated or silver-plated cladding.

### Contact Element

The adapter 1 comprises a contact element 7 forming a free end. The contact element 7 is included in the distal portion 5 of the adapter. The contact element 7 is intended to come into direct contact with the part to be tested.

The contact element 7 is mounted so as to be able to move with respect to the proximal portion 3 so that the distal portion 5 deforms when a force is exerted on the contact element 7. In particular, when the force is exerted in the axial direction Δ, the contact element 7 can be moved in this direction. At the point on the distal portion 5 occupied by the contact element 7, there is then a deformation of the distal portion 5. The distal portion 5 has at this point a length in the axial direction Δ that is smaller or larger depending on whether the contact element 7 has been moved closer to the proximal portion 3 or moved away from the proximal portion 3.

The adapter comprises a contact element mounted so as to be able to move with respect to the proximal portion so that, by applying a force to the contact element, the distal portion can deform so as better to be pressed against the part to be tested. This deformation depends on the shape of the part, so that the adapter adopts more the shape of the part. It then becomes possible to automatically move the device towards the part to be tested, without damaging it. Example, the adapter 1 comprises a deformable member 11 connected to the contact element 7 so as to mount the contact element 7 so as to be able to move with respect to the proximal portion 3. For example, the deformable member can be secured firstly to the proximal portion 3 and secondly to the contact element 7. Thus, when the deformable member 11 deforms, the distance between the contact element 7 and the proximal portion 3 changes, which makes it possible to mount the contact element 7 so as to be able to move with respect to the proximal portion 3.

The deformable member 11 can in particular be deformable in the axial direction Δ.

The deformable member 11 is advantageously selected from a compression spring, a single-acting cylinder or a double-acting cylinder. The spring and the cylinder are advantageously oriented so as to deform in the axial direction Δ.

When the adapter comprises a plurality of rods, at least one of the rods can be selected so as to be deformable in the axial direction Δ. A contact element can be attached to the end of the rod.

FIGS. 1, 3 and 4 show the case of a deformable member in the form of a single-acting cylinder.

The deformable member 11 can be attached to the contact element 7 either rigidly or in a pivot connection, or again in a ball-and-socket connection.

In the first case, there is no significant movement possible between the deformable member 11 and the contact element 7.

In the second case, there is significant movement possible between the deformable member 11 and the contact element 7 that is a rotation movement in a single direction.

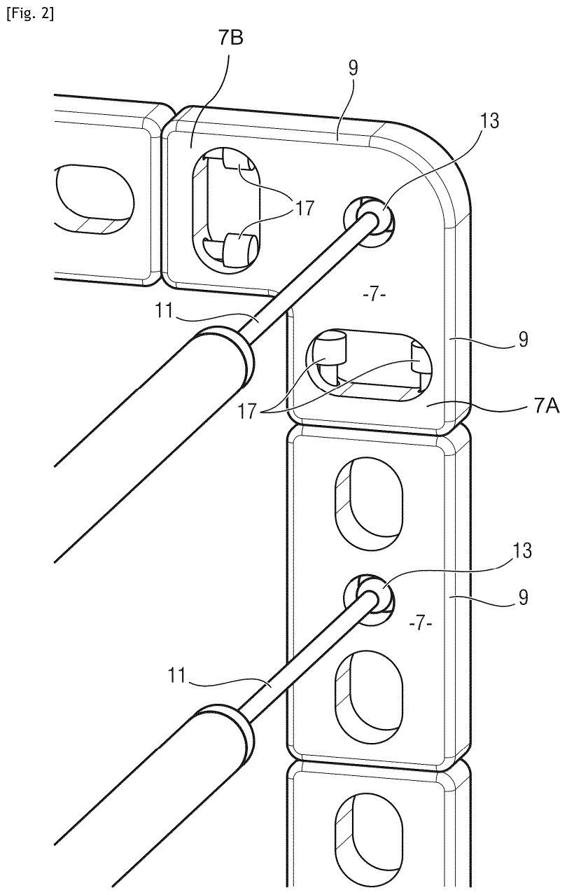

In the third case, there is significant movement possible between the deformable member 11 and the contact element 7 that is a rotation movement in the three directions in space. This case is shown in FIG. 2, where two contact elements 7 are each connected to a deformable member 11 in a ball-and-socket connection 13.

The contact element may be made from Teflon, elastomer or aluminium.

The contact element can be obtained by 3D printing of molten polymer threads, for example polyethylene.

Advantageously, when the adapter comprises a contact element mounted as to be able to move with respect to the proximal portion, the adapter can comprise an optical-isolation wall 28 that is deformable. In particular, the wall 28 can be deformed in the axial direction Δ, i.e., according to a stress that is applied to the wall 28, the length of the wall 28 in the axial direction can vary. The wall 28 can be shortened or lengthened in the axial direction. The deformable character of the wall 28 is local, i.e., for different angular positions defined around the axial direction Δ, the wall 28 can adopt different lengths in the axial direction Δ.

The wall 28 can be made deformable by incorporating therein a fabric, plastics material, pleated portions, and in particular portions pleated in an accordion or sections configured to nest together in the axial direction. FIG. 4 illustrates an example of a wall comprising portions pleated in an accordion in the axial direction Δ. The parts pleated in an accordion or the sections configured to nest together in the axial direction have sufficient mechanical clearance to allow different lengths of the wall 28 in the axial direction Δ at different angular positions around the axial direction Δ.

The device may be only partially in contact with the part. When the device and the part are put in contact, a more or less great gap effect is created between them. These gaps prevent the isolation of the exchanges between the device and the part with respect to the external environment. In other words, the energy emitted by the device towards the part is not the only energy received by the part and conversely the energy emitted by the part towards the device is not the only energy received by the device. This disturbs the excitation of the part by the device, the diffusion phenomenon and the signal acquired from the diffusion in the part by the detector. Moreover, the flashes of light that pass through the gaps may dazzle the operators.

The adapter comprising a contact element mounted so as to be able to move with respect to the proximal portion and an optical-isolation wall 28 that is deformable makes it possible to reduce the gaps between the adapter and the part to be analysed. By deforming, the distal portion causes a deformation of the wall. The distal portion adopts the shapes of the part and the adapter isolates the radiative exchanges between the device and the part with respect to the external environment.

### Form-Shape of the Contact Element

Advantageously, and as illustrated in FIG. 2, the contact element 7 has rounded or bevelled edges 9. Such edges make it possible to reduce and limit scratches inflicted on the part to be tested when the contact element 7 comes into contact with it.

In a first embodiment, the contact element has a spherical shape. Advantageously, the contact element has this shape when the deformable member 11 is connected to the contact element 7 rigidly. The rigid connection can in particular be configured so that the deformable member is aligned in a direction that passes through the centre of the spherical shape.

In a second embodiment, the contact element has a parallelepipedal shape. In particular, the contact element can adopt a pad shape, as shown in FIG. 2. This parallelepipedal shape is defined by three distances: a length, a width and a depth. The length is greater than the width, itself greater than the depth. The pad is preferably oriented so that the depth extends mainly in the axial direction Δ, the length and the depth then extending in directions orthogonal to each other and orthogonal to the axial direction Δ.

Advantageously, the contact element has this parallelepipedal shape when the deformable member 11 is connected to the contact elements 7 either in a pivot connection or in a ball-and-socket connection. In this way, when the contact element 7 comes in contact against the part to be tested, the pad is oriented so as to adopt the shape of the part more, i.e. to increase a contact surface between the part and the pad.

The adapter can be configured so that the deformable member is aligned in a direction that passes through the rotation axis of the pivot connection or the centre of rotation of the ball-and-socket connection. This makes it possible to increase the stability of the contact and to reduce the gaps during contact. Advantageously, the pivot connection or the ball-and-socket connection can be placed at the centre of the contact element 7.

### Plurality of ‘Deformable Member’ and ‘Contact Element’ Assemblies

The adapter 1 can comprise a plurality of contact elements 7, each contact element 7 being mounted so as to be able to move with respect to the proximal portion 3. The contact elements 7 can all have the same shape, for example a spherical or parallelepipedal shape. The contact elements 7 can also alternatively have different shapes.

Advantageously, each contact element 7 is mounted so as to be able to move with respect to the proximal portion 3 via a deformable member 11. The adapter 1 then comprises a plurality of deformable members 11, each deformable member 11 being associated with a contact element 7 so as to form a deformable member 11+contact element 7 assembly. The adapter 1 then comprises a plurality of ‘deformable member 11+contact element 7’ assemblies.

The various contact elements can be arranged in various ways and in particular they can be aligned in a closed perimeter. This closed perimeter gives the form of the distal portion. This perimeter can be polygonal in shape such as a square, a diamond, a rectangle, a parallelogram, a hexagon or an octagon or a circular or ellipsoidal shape. FIGS. 1, 3 and 4 illustrates the case of a perimeter that adopts a square shape.

Along this closed perimeter, the contact elements can be regularly distributed, i.e. the distance between two adjacent elements—i.e. two contact elements plus near neighbours—is constant from one pair of adjacent contact elements to another pair of adjacent elements. Here constant distance should be understood as a distance that does not vary by more than 5% from one pair of adjacent contact elements to another pair of adjacent elements. The adjacent elements can be defined as contiguous when they are in contact with each other or almost in contact with each other.

When the various contact elements are aligned in a closed perimeter, this perimeter is a distal perimeter. The various deformable members are advantageously oriented in the axial direction Δ and secured to the proximal portion at securing points that are distributed along a proximal perimeter with the same shape as the distal perimeter. When the contact elements are regularly distributed along the distal perimeter, the attachment points are advantageously regularly distributed along the proximal perimeter.

In the case where the perimeter has a polygonal shape and therefore defines vertices, two contact elements located at the vertices can be bevelled in a complementary manner and facing each other so as to define the vertex of the polygonal shape. Alternatively, and with reference to FIG. 2, a contact element 7 located at a vertex can have a shape having two sub-portions 7A and 7B on either side of the vertex, the first sub-portion 7A defining an angle with respect to the second sub-portion 7B, the angle corresponding to the angular deviation of the perimeter at the vertex. In the example in FIG. 2, this angle is a right angle.

In the case where the contact elements each adopt an identical parallelepipedal shape, the length of each shape can be oriented along the perimeter and the width can be oriented orthogonally to the perimeter.

It possible to connect two adjacent contact elements by an elastic element. In this way, the movements of the contact elements 7 in contact with the part to be tested are dependent on each other.

In the case where the contact elements each adopt an identical parallelepipedal shape, the contact elements can advantageously be arranged contiguous in pairs, two contiguous contact elements being directly connected by an elastic element 17. This supplementary connection makes it possible to preserve continuity of the perimeter defined by the various contact elements 7.

Preferably, each pair of two contiguous contact elements can be connected by two elastic elements 17 connected to the contact elements by a mounting in parallel. This connection between two contiguous elements also makes it possible to avoid a rotation of one contact element with respect to the other about an elastic element.

When the adapter 1 comprises a plurality of contact elements 7 and also comprises a deformable optical-isolation wall 28 surrounding the recess 30, the isolation wall 28 can be secured on an external edge of the various contact elements. In this way the ingress of radiation into the adapter or the exit of radiation out of the adapter between the contact elements 7 and the proximal portion 3 is limited.

### System for Non-Destructive Testing of a Part by Radiation

A system for non-destructive testing is also proposed, comprising an adapter 1 as has been able to be presented up until now and a device for non-destructive testing by electromagnetic radiation also presented above in the text. In such a system for non-destructive testing by electromagnetic radiation, the proximal part of the adapter 1 is rigidly secured to the non-destructive testing device 22.

The system can advantageously furthermore comprise a carriage and a robotic arm associated with a control system, the carriage supporting the robotic arm and the robotic arm supporting the non-destructive testing device. The robotic arm is configured to move and orient the device in space. It is thus possible to place the device precisely facing the part to be tested. The robotic arm can next press the testing device against the part so as to deform the distal part of the adapter. The distal part is thus adapted to the shape of the part to be tested. Once the measurement has been made, the robotic arm can move the device and place it facing another portion of the part to be tested to make a second acquisition.

### Method for Non-Destructive Testing of a Part by Radiation

The invention furthermore relates to a method of this type comprising the following steps:
putting a contact element of a testing system in contact with the part,
applying a force to the contact element, and
moving the contact element with respect to the rest of the system under the action of the force and deforming the system according to the shape of the part.

Advantageously, it is possible to use an adapter comprising a plurality of contact elements 7 the number of which is fixed according to the geometry of the part to be tested.

The geometry of the part to be tested can in particular be defined by a mean length, denoted L, of the part and a mean radius of curvature, denoted R, of the part.

For this purpose, the method can comprise a step of determining the mean length L and the mean radius of curvature R of the part. For example, it is possible to use a telemeter or a time of flight (ToF) camera to determine the mean radius of curvature R via a determination of a relative distance between the telemeter and the part. For determining the total length to be tested, a robot can be used.

The number of contact elements can be fixed according to the mean length and the mean radius of curvature.

For example, it can be chosen to increase the number of contact elements
when the mean radius of curvature and decreases, or
when the mean length increases.

Such variation may in particular be based on the ratio of the mean radius of curvature to the mean length, and it can be chosen to increase the number of contact elements when the ratio of the mean radius of curvature to the mean length decreases. In this way, it is possible to adapt the number of pads to the structure or geometry of the part to be tested.

One way of fixing the number of contact elements can comprise in particular the following steps:
determining an integer part of a ratio of the mean radius of curvature to the mean length, and
determining a difference between the number 10 and the integer part,
   the number of contact elements included in the adapter being equal to four times the difference.

Denoting E the integer part function and N the number of contact elements, the preceding steps consist in making the following calculation: N=4×(10−E(R/L)).

Optionally, when the contact elements are distributed on a square-shaped closed perimeter, it is also possible to choose the number of contact elements 7 per side of a square equal to 10−E(R/L).

For the particular case where this integer part is greater than or equal to 10, eight contact elements may suffice, for example one contact element per side of the square plus one contact element per corner of the square.

Finally, it is possible to add to the non-destructive testing method the following steps:
emitting radiation towards the part through the testing system, and
acquiring, through the testing system, a temporal response of heat diffusion in the part.

A processing of the acquired image can furthermore be implemented to locate any local thermal contrasts associated with defects in the part in the imaged zone.

The method can be implemented to image a second zone and, for this purpose, provision can be made for a retraction of the system with respect to the part to be tested and an offsetting of the system with respect to the zone already inspected to inspect a second zone on the part.

The steps previously presented for imaging and analysing the first zone can be implemented for imaging and analysing the second zone.

A plurality of zones can be imaged and analysed successively. The part to be tested can be divided into various zones that define the whole of its surface so that it is possible to make a complete sweep of the part by imaging and analysing the various zones.

The movements of the system and the emission and acquisition sequences can be automated by means of a central control system. A central control system may for example comprise a carriage and a robotic arm associated with a control system, as presented above.

1. An adapter for a device for non-destructive testing by electromagnetic radiation, the adapter comprising:
a proximal part configured to be attached to a testing device, and
a distal part comprising a contact element forming a free end and mounted so as to be movable with respect to the proximal part so that the distal part deforms when a force is applied to the contact element,
a deformable member connected to the contact element so as to mount the contact element so as to be able to move with respect to the proximal part, the contact element being connected to the deformable member via a ball-and-socket or pivot connection, the contact element having a parallelepipedal shape.

2. The adapter according to claim 1, wherein the contact element has rounded or bevelled edges.

3. The adapter according to claim 1, wherein the contact element and the deformable member form a first assembly, the adapter comprising a plurality of assemblies.

4. The adapter according to claim 3, wherein the contact elements are arranged contiguous in pairs, two contiguous contact elements being directly connected by an elastic element.

5. The adapter according to claim 4, wherein the elastic element is a first elastic element, the two contiguous contact elements furthermore being directly connected by a second elastic element, the first and second elastic elements being connected to the contact elements by mounting in parallel.

6. The adapter according to claim 1, wherein the adapter extends from the proximal portion to the distal portion along an axial direction, the adapter being hollow so as to have a recess in the axial direction, the recess emerging outside the adapter through the proximal portion and through the distal portion, the adapter comprising an optical isolation wall surrounding the recess, the wall comprising an external portion opaque to electromagnetic radiation, and an internal portion reflective for electromagnetic radiation, the electromagnetic radiation being intended to be used for the non-destructive testing.

7. The adapter according to claim 6, wherein the optical-isolation wall is deformable.

8. A system for non-destructive testing by electromagnetic radiation, comprising
a device for non-destructive testing by electromagnetic radiation, the device comprising a radiation source and a radiation detector,
an adapter according to claim 1, the proximal portion being rigidly secured to the non-destructive testing device.

9. A method for non-destructive testing by electromagnetic radiation, comprising the following steps:
putting a contact element of a testing system in contact with the part,
applying a force to the contact element, and
moving the contact element with respect to the rest of the system under the action of the force and deforming the system according to the shape of the part, the deformation including a rotation of the contact element with respect to the rest of the testing system.

10. The method according to claim 9, comprising the following steps:
emitting, through the testing system, radiation towards the part, and
acquiring, through the testing system, a temporal response of heat diffusion in the part.
